(19) United States
(12) Patent Application Publication
(10) Pub. No.: US 2026/0182293 A1
(43) Pub. Date: Jun. 25, 2026

(54) SEALING STRUCTURE, PRESSURE CONTAINER AND SEALING METHOD

(71) Applicant: Tokyo Electron Limited, Tokyo (JP)

(72) Inventors: Chun Hung HUNG, Hsinchu City (TW); Chun Hung HUNG, Hsinchu City (TW); Toru ISHII, Iwate (JP); Reita IGARASHI, Iwate (JP); Cheng Hsiung LEE, Hsinchu City (TW); Fu Chieh HSU, Hsinchu City (TW); Chi Ming KUO, Hsinchu City (TW)

(21) Appl. No.: 19/414,967

(22) Filed: Dec. 10, 2025

Related U.S. Application Data
(60) Provisional application No. 63/738,336, filed on Dec. 23, 2024.

(51) Int. Cl. H10P 72/00

(52) U.S. Cl. CPC H10P 72/0402

(57) ABSTRACT

A sealing structure is provided. The sealing structure includes a first portion and a second portion. The first portion defines a first groove opening toward a first direction. The second portion defines a second groove opening toward a second direction opposite to the first direction. The first portion surrounds the second portion.

### CROSS-REFERENCE TO RELATED APPLICATIONS

The present application claims the benefit of U.S. provisional application No. 63/738,336, filed Dec. 23, 2024, the contents of which are incorporated herein by reference.

### BACKGROUND

### 1. Field of the Invention

The present disclosure relates to a sealing structure, a pressure container and a sealing method, and in particular, to a sealing structure defining at least one groove, a pressure container including the same and a sealing method corresponding the same.

### 2. Description of the Related Art

In a conventional processing method involving high-pressure gas environment, a workpiece is typically placed inside a pressure container that is configured to withstand and maintain elevated gas pressures required for various processing operations (see, for example, U.S. Pat. No. 8,936,834 B2, TW 202420473 A, and the like). Such pressure container is commonly employed in industries including semiconductor manufacturing, chemical vapor deposition, materials synthesis, and surface treatment, where precise control over the gaseous environment is essential to achieve desired material properties and process results. The pressure container typically includes an inner chamber configured for accommodating a first gas and an outer chamber configured for accommodating a second gas different from the first gas. A significant technical challenge associated with this configuration lies in maintaining strict separation between the first gas and the second gas. Any leakage or unintended mixing between these gases will adversely affect the processing results and the product quality. Thus, an effective sealing or an effective isolation at the interface between the inner and outer chambers is a critical issue.

### SUMMARY

In some embodiments, a sealing structure includes a first portion and a second portion. The first portion defines a first groove opening toward a first direction. The second portion defines a second groove opening toward a second direction opposite to the first direction. The first portion surrounds the second portion.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates an exploded cross-sectional view of a pressure container according to some embodiments of the present disclosure;

FIG. 2 illustrates an enlarged view of an area “A” of FIG. 1;

FIG. 3 illustrates an assembled cross-sectional view of the pressure container of FIG. 1;

FIG. 4 illustrates an enlarged view of an area “B” of FIG. 3;

FIG. 5 illustrates an enlarged view of an area “C” of FIG. 4;

FIG. 6 illustrates an exploded cross-sectional view of a pressure container according to some embodiments of the present disclosure;

FIG. 7 illustrates an enlarged view of an area “D” of FIG. 6;

FIG. 8 illustrates an assembled cross-sectional view of the pressure container of FIG. 6;

FIG. 9 illustrates an enlarged view of an area “E” of FIG. 8;

FIG. 10 illustrates an enlarged view of an area “F” of FIG. 9; and

FIG. 11 illustrates a cross-sectional view of a sealing structure according to some embodiments of the present disclosure.

### DETAILED DESCRIPTION

The components, values, operations, materials and configurations in the following disclosure are merely embodiments or examples and are not intended to be limiting. For example, a first element being formed over or on a second element may include different implementations. The first element and the second element may be in direct contact. Alternatively, the first element and the second element may not be in direct contact, and an additional element between the first element and the second element may be included.

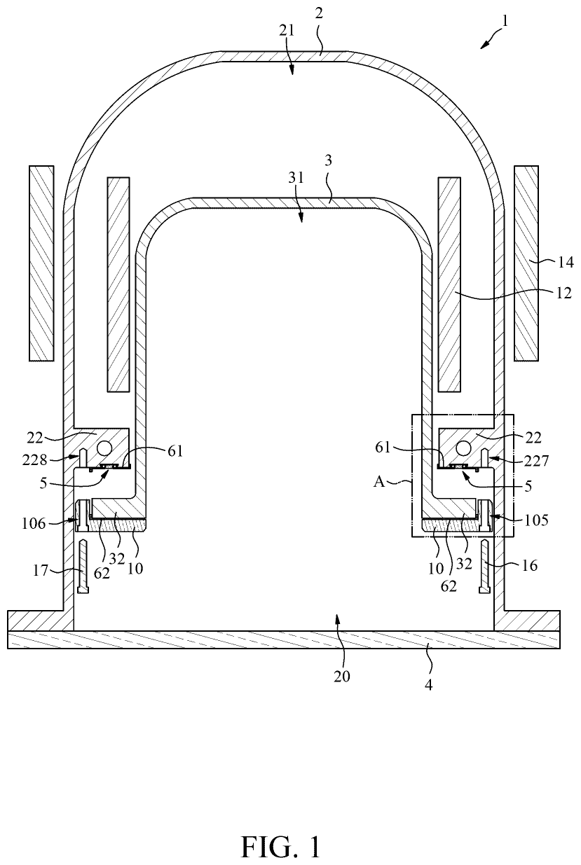

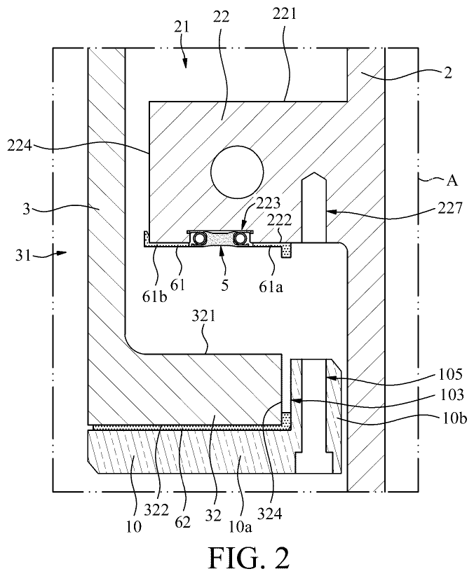

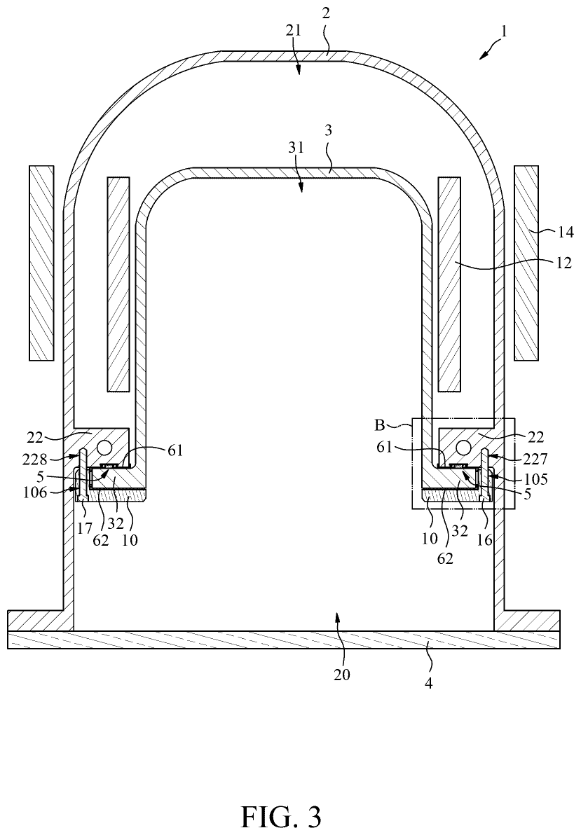

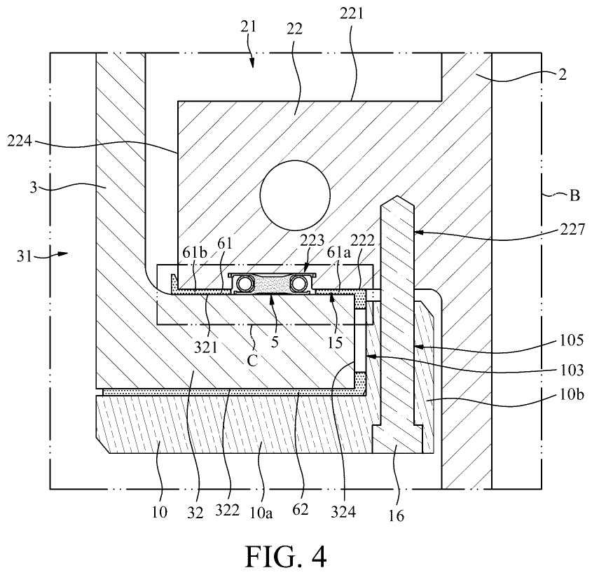

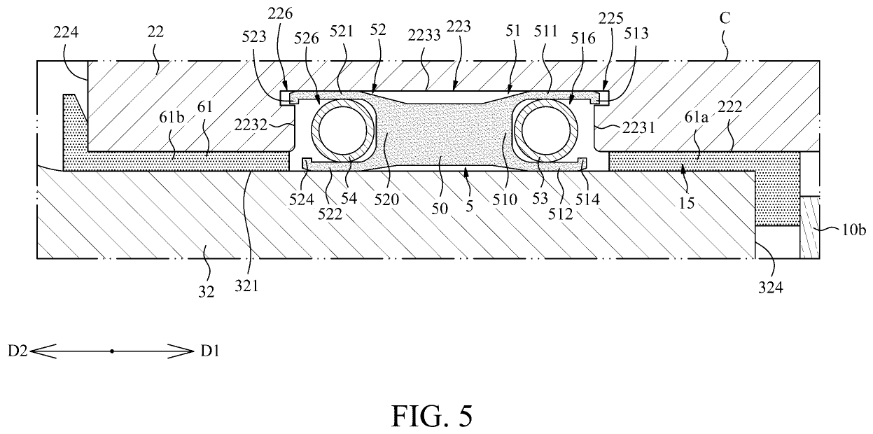

FIG. 1 illustrates an exploded cross-sectional view of a pressure container 1 according to some embodiments of the present disclosure. FIG. 2 illustrates an enlarged view of an area “A” of FIG. 1. FIG. 3 illustrates an assembled cross-sectional view of the pressure container 1 of FIG. 1. FIG. 4 illustrates an enlarged view of an area “B” of FIG. 3. FIG. 5 illustrates an enlarged view of an area “C” of FIG. 4. The pressure container 1 may be a semiconductor equipment with dual chamber or an annealing equipment. The pressure container 1 may be also referred to as “a pressure vessel” or “a high pressure equipment”.

As shown in FIG. 1 and FIG. 2, the pressure container 1 may include an outer chamber 2, an inner chamber 3, a sealing structure 5, a heater 12, a cooler 14, a lid 4, a base portion 10, a plurality of fasteners 16, 17, an upper buffer material 61 and a lower buffer material 62. The outer chamber 2 may be an outer housing, an outer tube or an outer vessel, and may include a metal material such as stainless steel. The outer chamber 2 may define a first cavity 21 (or a first accommodating space or a first gas region). The outer chamber 2 may include a first fixing portion 22 (or a first flange) located on an inner surface of the outer chamber 2. Thus, the first fixing portion 22 may extend inward and toward the inner chamber 3. The first fixing portion 22 may be a ring structure or an annular structure. The first fixing portion 22 may have a top surface 221, a bottom surface 222 opposite to the top surface 221 and an inner surface 224 extending between the top surface 221 and the bottom surface 222. The first fixing portion 22 may define a first hole 227 and a first hole 228 recessed from the bottom surface 222. For example, each of the first hole 227 and the first hole 228 may be a screw hole. In addition, a lower portion of the outer chamber 2 may define an opening 20.

In some embodiments, the outer chamber 2 may further define a first gas intake channel (not shown), a first gas exhaust channel (not shown), a second gas intake channel (not shown) and a second gas exhaust channel (not shown). The first gas intake channel and the first gas exhaust channel may be disposed above the first fixing portion 22, and may extend through the sidewall of the outer chamber 2 so as to communicate the first cavity 21 and the external space outside the outer chamber 2. Thus, a first gas (e.g., an inert gas) may enter the first cavity 21 through the first gas intake channel, and may leave the first cavity 21 through the first gas exhaust channel. In addition, the second gas intake channel and the second gas exhaust channel may be disposed under the first fixing portion 22, and may extend through the sidewall of the outer chamber 2 so as to communicate a second cavity 31 of the inner chamber 3 and the external space outside the housing 3. Thus, a second gas (e.g., a process gas) may enter the second cavity 31 through the second gas intake channel, and may leave the second cavity 31 through the second gas exhaust channel.

The inner chamber 3 and the heater 12 may be disposed in the first cavity 21 of the outer chamber 2. The inner chamber 3 may be an inner housing such as a quartz tube. The inner chamber 3 may define a second cavity 31 (or a second accommodating space) in communication with the opening 20 of the outer chamber 2. The inner chamber 3 may be also referred to as “an inner pressure vessel”. The inner chamber 3 may include a second fixing portion 32 (or a second flange) located on an outer surface of the inner chamber 3. Thus, the second fixing portion 32 may extend outward and toward the outer chamber 2. The second fixing portion 32 may be a ring structure or an annular structure. The second fixing portion 32 may be disposed under the first fixing portion 22. Alternatively, the second fixing portion 32 may vertically overlap the first fixing portion 22. The second fixing portion 32 may have a top surface 321, a bottom surface 322 opposite to the top surface 321 and an outer lateral surface 324 extending between the top surface 321 and the bottom surface 322.

In addition, the heater 12 may be disposed around the inner chamber 3 to heat the inner chamber 3 to make the temperature in the second cavity 31 reach the process temperature. The heater 12 may surround an upper end of the inner chamber 3. The cooler 14 may be disposed around the outer chamber 2 to adjust or control the temperature in the second cavity 31 and the temperature in the first cavity 21. The cooler 14 may be disposed outside the outer chamber 2, and may surround an upper end of the outer chamber 2.

In one embodiment, the outer chamber 2 may be also referred to as “a first element”, and the inner chamber 3 may be also referred to as “a second element”. The lid 4 may include a metal material such as stainless steel. The lid 4 may be disposed in the first cavity 21, and under the inner chamber 3. The lid 4 may be configured to cover the opening 20 of the outer chamber 2. The lid 4 may be also referred to as “a cover” or “a cap”.

The base portion 10 (e.g., a base element) may be disposed under the second fixing portion 32 of the inner chamber 3. The base portion 10 may include a metal material such as stainless steel. The base portion 10 may be a ring structure or an annular structure. The base portion 10 may be also referred to as “a supporting element” or “a clamping element”. The base portion 10 may include a first portion 10a and a second portion 10b surrounding the first portion 10a. A thickness of the second portion 10b may be greater than a thickness of the first portion 10a. Thus, the second portion 10b and the first portion 10a may collectively define a recess portion 103 (or a cavity). The second fixing portion 32 of the inner chamber 3 may be disposed in the recess portion 103, and may be supported by the first portion 10a of the base portion 10. Thus, the bottom surface 322 of the second fixing portion 32 may face the first portion 10a of the base portion 10. The outer lateral surface 324 of the second fixing portion 32 may face the second portion 10b of the base portion 10.

The second portion 10b of the base portion 10 may define a through hole 105 (e.g., a second hole) and a through hole 106 extending through the second portion 10b of the base portion 10. For example, each of the through hole 105 and the through hole 106 may be a screw hole. The base portion 10 may be detachably attached to the first fixing portion 22 of the outer chamber 2. For example, the base portion 10 may be secured to the first fixing portion 22 of the outer chamber 2 through the fasteners 16, 17 (e.g., screws), so as to clamp the second fixing portion 32 of the inner chamber 3 between the base portion 10 and the first fixing portion 22 of the outer chamber 2. The fasteners 16, 17 (e.g., screws) may extend through the base portion 10, and may extend into the first fixing portion 22 of the outer chamber 2. The fasteners 16, 17 (e.g., screws) may not extend through the second fixing portion 32 of the inner chamber 3. For example, the fastener 16 (e.g., the screw) may extend through the through hole 105 of the second portion 10b of the base portion 10 and may be screwed into the first hole 227 of the first fixing portion 22. The fastener 17 (e.g., the screw) may extend through the through hole 106 of the second portion 10b of the base portion 10 and may be screwed into the first hole 228 of the first fixing portion 22, as shown in FIG. 4.

As shown in FIG. 4 and FIG. 5, a gap 15 may be formed between the bottom surface 222 of the first fixing portion 22 of the outer chamber 2 and the top surface 321 of the second fixing portion 32 of the inner chamber 3. The sealing structure 5 may be disposed adjacent to the gap 15, and configured to seal the gap 15. The sealing structure 5 may be configured to isolate the first cavity 21 of the outer chamber 2 from the second cavity 31 of the inner chamber 3 so to prevent the communication between the first cavity 21 of the outer chamber 2 and the second cavity 31 of the inner chamber 3. In some embodiments, the first fixing portion 22 may define a recess 223 for accommodating the sealing structure 5. The recess 223 may be recessed from the bottom surface 222 of the first fixing portion 22, and may be communicated with the gap 15. Thus, the recess 223 may be a portion of the gap 15. The recess 223 may have a first inner surface 2231, a second inner surface 2232 opposite to the first inner surface 2231, and a top inner surface 2233 extending between the first inner surface 2231 and the second inner surface 2232.

The first fixing portion 22 may further define a first opening 225 (or a first notch) and a second opening 226 (or a second notch). The first opening 225 may be recessed from the first inner surface 2231 of the recess 223, and the second opening 226 may be recessed from the second inner surface 2232 of the recess 223. Both the first opening 225 and the second opening 226 may be communicated with the recess 223. A top inner surface of the first opening 225 may be a portion of the top inner surface 2233 of the recess 223. A top inner surface of the second opening 226 may be a portion of the top inner surface 2233 of the recess 223.

As shown in FIG. 5, the sealing structure 5 may include a connecting portion 50, a first portion 51, a second portion 52, a first supporter 53 and a second supporter 54. The connecting portion 50 may be a main portion, and may connect the first portion 51 and the second portion 52. The first portion 51 may define a first groove 516 (or a first opening or a first cavity) that opens toward a first direction D1 or the right side. The first supporter 53 (e.g., a first expander, a first sustainer or a first elastic component) may be disposed in the first groove 516. The first supporter 53 may provide a pretension force to open the first groove 516. The second portion 52 may define a second groove 526 (or a second opening or a second cavity) that opens toward a second direction D2 or the left side opposite to the first direction D1. The first portion 51 may surround the second portion 52. The second supporter 54 (e.g., a second expander, a second sustainer or a second elastic component) may be disposed in the second groove 526. The second supporter 54 may provide a pretension force to open the second groove 526.

A material of the connecting portion 50, the first portion 51 and the second portion 52 may include resin or polymer such as fluorine resin or rubber. The fluorine resin may include polytetrafluoroethylene (PTFE), polyetheretherketone (PEEK), polystyrene sulfonate (PSS), polyimide (PI), polyphenylene sulfide (PPS), lampricide 3-trifluoromethyl-4-nitrophenol (TFM). For example, the material of the connecting portion 50, the first portion 51 and the second portion 52 may include a combination of PTFE and carbon, a combination of PTFE and carbon fiber or a combination of PTFE and PEEK. In addition, a material of the first supporter 53 and the second supporter 54 may include metal such as copper or stainless steel. A hardness or rigidity of the material of the first supporter 53 and the second supporter 54 may be greater than a hardness or rigidity of the material of the connecting portion 50, the first portion 51 and the second portion 52.

In one embodiment, each of the connecting portion 50, the first portion 51 and the second portion 52 may be a ring structure or an annular structure from a top view. The connecting portion 50, the first portion 51 and the second portion 52 may be integral with each other. There may be no interface between the connecting portion 50, the first portion 51 and the second portion 52. That is, the first portion 51 and the second portion 52 may extend from the connecting portion 50. Alternatively, the first portion 51 and the second portion 52 may be separated from each other.

In one embodiment, both the first supporter 53 and the second supporter 54 may be resilient structures. Both the first supporter 53 and the second supporter 54 may be hollow structures or solid structures. In one embodiment, both the first supporter 53 and the second supporter 54 may be springs. Each of the first supporter 53 and the second supporter 54 may be a ring structure or an annular structure from a top view. Each of the first supporter 53 and the second supporter 54 may be in a circular shape, a rectangular shape or other shape in a cross-sectional view.

As shown in FIG. 5, the first portion 51 may include a first main portion 510, a first upper portion 511 and a first lower portion 512. The first main portion 510 may connect the connecting portion 50. The first main portion 510, the first upper portion 511 and the first lower portion 512 collectively define the first groove 516. Both the first upper portion 511 and the first lower portion 512 extend from the first main portion 510. One end of the first upper portion 511 may include a first upper extending portion 513 (e.g., a bulge) extending toward the first lower portion 512. One end of the first lower portion 512 may include a first lower extending portion 514 (e.g., a bulge) extending toward the first upper portion 511.

The first main portion 510, the first upper portion 511 and the first lower portion 512 collectively form a U-shaped structure. The first upper portion 511 and the first upper extending portion 513 collectively form an L-shaped structure. The first lower portion 512 and the first lower extending portion 514 collectively form an L-shaped structure. In addition, a length of the first upper portion 511 may be greater than a length of the first lower portion 512. Thus, the first upper extending portion 513 may be disposed in the first opening 225. The first opening 225 may be used for accommodating the first upper extending portion 513 of the first portion 51 of the sealing structure 5.

The second portion 52 may include a second main portion 520, a second upper portion 521 and a second lower portion 522. The second main portion 520 may connect the connecting portion 50. The second main portion 520, the second upper portion 521 and the second lower portion 522 collectively define the second groove 526. Both the second upper portion 521 and the second lower portion 522 extend from the second main portion 520. One end of the second upper portion 521 may include a second upper extending portion 523 (e.g., a bulge) extending toward the second lower portion 522. One end of the second lower portion 522 may include a second lower extending portion 524 (e.g., a bulge) extending toward the second upper portion 521.

The second main portion 520, the second upper portion 521 and the second lower portion 522 collectively form a U-shaped structure. The second upper portion 521 and the second upper extending portion 523 collectively form an L-shaped structure. The second lower portion 522 and the second lower extending portion 524 collectively form an L-shaped structure. In addition, a length of the second upper portion 521 may be greater than a length of the second lower portion 522. Thus, the second upper extending portion 523 may be disposed in the second opening 226. The second opening 226 may be used for accommodating the second upper extending portion 523 of the second portion 52 of the sealing structure 5.

The upper buffer material 61 (e.g., an upper soft gasket) and the lower buffer material 62 (e.g., a lower soft gasket) may include resin or polymer such as fluorine resin or rubber. The fluorine resin may include polytetrafluoroethylene (PTFE), polyetheretherketone (PEEK), polystyrene sulfonate (PSS), polyimide (PI), polyphenylene sulfide (PPS), lampricide 3-trifluoromethyl-4-nitrophenol (TFM). For example, the upper buffer material 61 and the lower buffer material 62 may include a combination of PTFE and carbon, a combination of PTFE and carbon fiber or a combination of PTFE and PEEK.

The upper buffer material 61 may be interposed between the bottom surface 222 of the first fixing portion 22 of the outer chamber 2 and the top surface 321 of the second fixing portion 32 of the inner chamber 3 so as to prevent the inner chamber 3 from contacting the outer chamber 2. That is, the upper buffer material 61 may be disposed in the gap 15. In some embodiments, the upper buffer material 61 may include a first upper buffer material 61a adjacent to the first portion 51 of the sealing structure 5 and a second upper buffer material 61b adjacent to the second portion 52 of the sealing structure 5. In some embodiments, the first upper buffer material 61a may be separated from the second upper buffer material 61b. Each of the first upper buffer material 61a and the second upper buffer material 61b may be a ring structure or an annular structure from a top view. In some embodiments, the first upper buffer material 61a may further extend to contact the outer lateral surface 324 of the second fixing portion 32 and the second portion 10b of the base portion 10. The second upper buffer material 61b may further extend to contact the inner surface 224 of the first fixing portion 22.

In addition, the lower buffer material 62 may be interposed between the bottom surface 322 of the second fixing portion 32 of the inner chamber 3 and the first portion 10a of the base portion 10 so as to prevent the inner chamber 3 from contacting the base portion 10. The lower buffer material 62 may be disposed in the recess portion 103 of the base portion 10. The lower buffer material 62 may further extend to contact the outer lateral surface 324 of the second fixing portion 32, and may contact the second portion 10b of the base portion 10.

As shown in FIG. 3 and FIG. 5, the outer chamber 2 and the inner chamber 3 may be secured to each other through the base portion 10 and the fasteners 16, 17 by, for example, screwing. Meanwhile, the first supporter 53 may compress the first upper portion 511 of the first portion 51 to create a firm contact with the outer chamber 2. Alternatively, the top inner surface 2233 of the recess 223 of the first fixing portion 22 of the outer chamber 2 may compress the first upper portion 511 of the first portion 51 to contact the first supporter 53, so as to create a firm contact between the first upper portion 511 of the first portion 51 and the top inner surface 2233 of the recess 223 of the first fixing portion 22 of the outer chamber 2.

Simultaneously, the first supporter 53 may compress the first lower portion 512 of the first portion 51 to create a firm contact with the inner chamber 3. Alternatively, the top surface 321 of the second fixing portion 32 of the inner chamber 3 may compress the first lower portion 512 of the first portion 51 to contact the first supporter 53, so as to create a firm contact between the first lower portion 512 of the first portion 51 and the top surface 321 of the second fixing portion 32 of the inner chamber 3.

Thus, the first upper portion 511 of the first portion 51 may firmly contact the top inner surface 2233 of the recess 223 of the first fixing portion 22 of the outer chamber 2 when the first upper portion 511 is compressed or pushed by the first supporter 53. The first lower portion 512 of the first portion 51 may firmly contact the top surface 321 of the second fixing portion 32 of the inner chamber 3 when the first lower portion 512 is compressed or pushed by the first supporter 53. The second fixing portion 32 of the inner chamber 3 and the first fixing portion 22 of the outer chamber 2 may clamp the first upper portion 511 of the first portion 51, the first supporter 53 and the first lower portion 512 of the first portion 51.

In addition, the second supporter 54 may compress the second upper portion 521 of the second portion 52 to create a firm contact with the outer chamber 2. Alternatively, the top inner surface 2233 of the recess 223 of the first fixing portion 22 of the outer chamber 2 may compress the second upper portion 521 of the second portion 52 to contact the second supporter 54, so as to create a firm contact between the second upper portion 521 of the second portion 52 and the top inner surface 2233 of the recess 223 of the first fixing portion 22 of the outer chamber 2. Simultaneously, the second supporter 54 may compress the second lower portion 522 of the second portion 52 to create a firm contact with the inner chamber 3. Alternatively, the top surface 321 of the second fixing portion 32 of the inner chamber 3 may compress the second lower portion 522 of the second portion 52 to contact the second supporter 54, so as to create a firm contact between the second lower portion 522 of the second portion 52 and the top surface 321 of the second fixing portion 32 of the inner chamber 3.

Thus, the second upper portion 521 of the second portion 52 may firmly contact the top inner surface 2233 of the recess 223 of the first fixing portion 22 of the outer chamber 2 when the second upper portion 521 is compressed or pushed by the second supporter 54. The second lower portion 522 of the second portion 52 may firmly contact the top surface 321 of the second fixing portion 32 of the inner chamber 3 when the second lower portion 522 is compressed or pushed by the second supporter 54. The second fixing portion 32 of the inner chamber 3 and the first fixing portion 22 of the outer chamber 2 may clamp the second upper portion 521 of the second portion 52, the second supporter 54 and the second lower portion 522 of the second portion 52.

The sealing structure 5 may have an improved sealing ability to seal the recess 223 of the first fixing portion 22 of the outer chamber 2 and the gap 15 since there may be at least four firm contact points. Thus, an effective sealing or an effective isolation at the gap 15 between the inner chamber 3 and the outer chamber 2 may be achieved. That is, the sealing structure 5 may perform a robust sealing mechanism or a robust isolation at the interface between the inner chamber 3 and the outer chamber 2. Therefore, a yield of a workpiece to be processed in the inner chamber 3 may be improved.

As shown in the embodiment illustrated in FIG. 3, a large pressure difference may be formed between a first pressure of a first gas in the outer chamber 2 and a second pressure of a second gas in the inner chamber 3. For example, one of the first pressure and the second pressure may be about 200 atm, and the other one of the first pressure and the second pressure may be about 1 atm. The design of the sealing structure 5 can prevent the high-pressure first gas in the first cavity 21 of the outer chamber 2 from entering the low-pressure second cavity 31 of the inner chamber 3 or prevent the high-pressure second gas in the second cavity 31 of the inner chamber 3 from entering the low-pressure first cavity 21 of the outer chamber 2.

In one embodiment, if the first gas in the first cavity 21 of the outer chamber 2 has a high pressure, the high pressure first gas will enter the second groove 526 of the second portion 52 to stretch the second groove 526. Thus, the second upper portion 521 of the second portion 52 may contact the top inner surface 2233 of the recess 223 of the first fixing portion 22 of the outer chamber 2 more firmly. The second lower portion 522 of the second portion 52 may contact the top surface 321 of the second fixing portion 32 of the inner chamber 3 more firmly. Similarly, if the second gas in the second cavity 31 of the inner chamber 3 has a high pressure, the high pressure second gas will enter the first groove 516 of the first portion 51 to stretch the first groove 516. Thus, the first upper portion 511 of the first portion 51 may contact the top inner surface 2233 of the recess 223 of the first fixing portion 22 of the outer chamber 2 more firmly. The first lower portion 512 of the first portion 51 may contact the top surface 321 of the second fixing portion 32 of the inner chamber 3 more firmly.

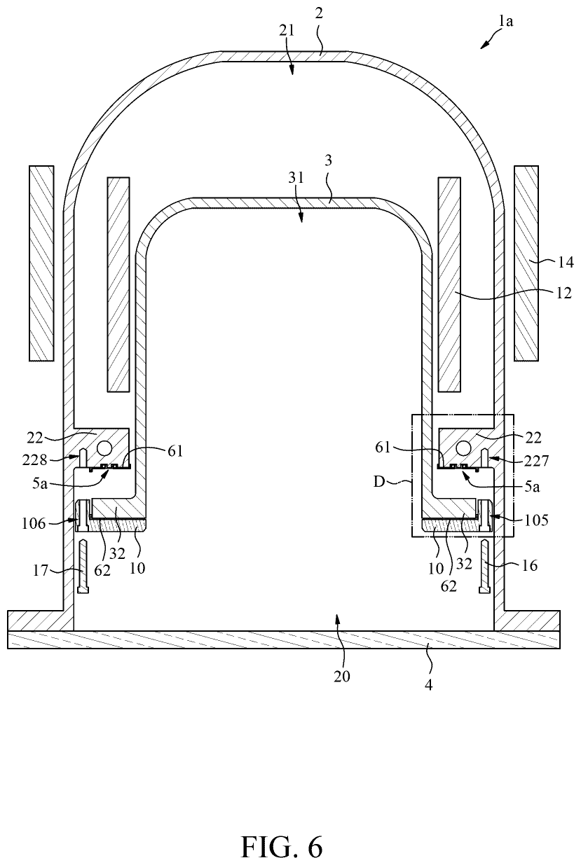

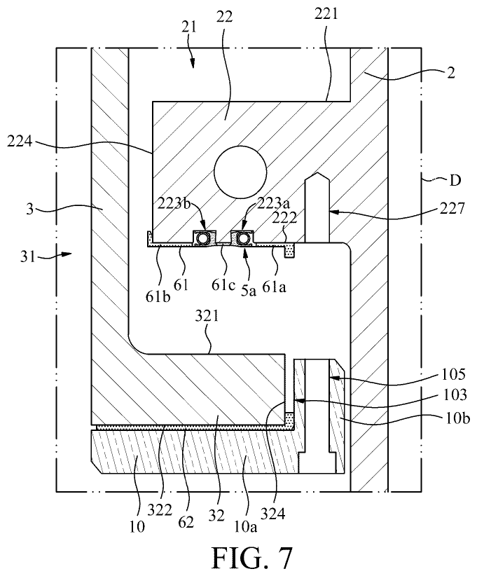

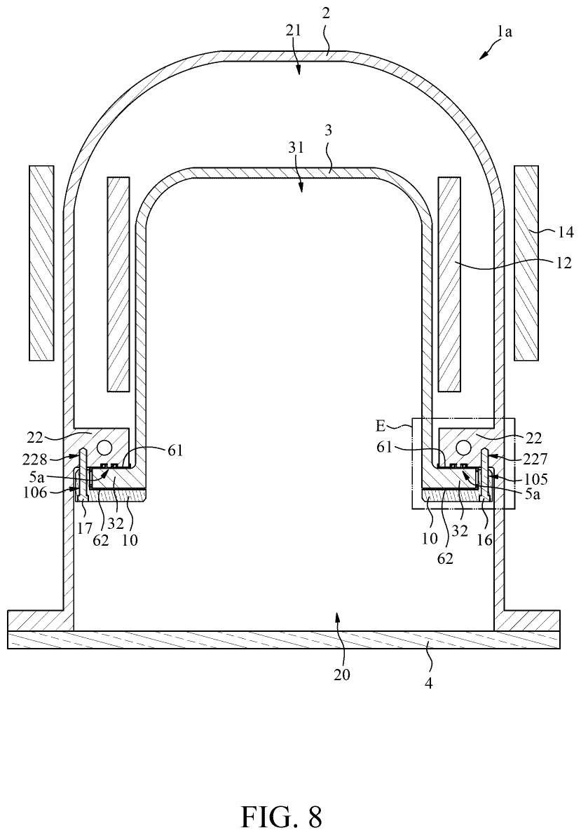

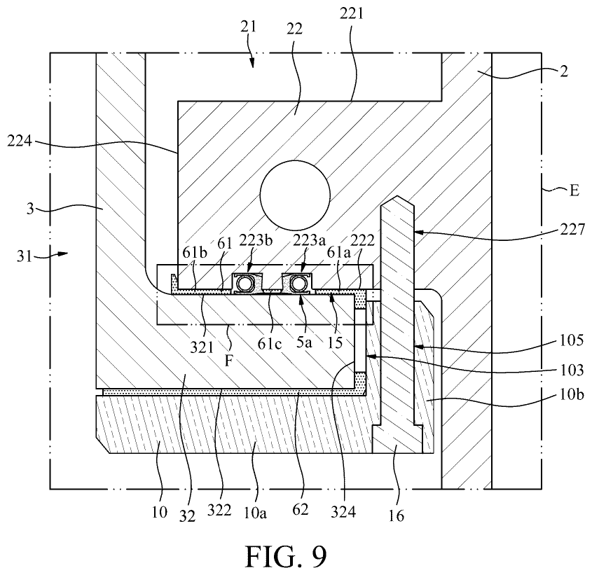

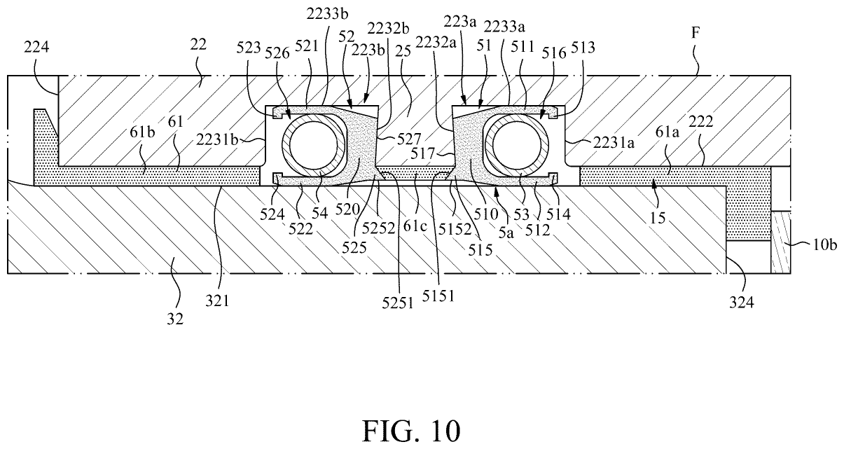

FIG. 6 illustrates an exploded cross-sectional view of a pressure container 1a according to some embodiments of the present disclosure. FIG. 7 illustrates an enlarged view of an area “D” of FIG. 6. FIG. 8 illustrates an assembled cross-sectional view of the pressure container 1a of FIG. 6. FIG. 9 illustrates an enlarged view of an area “E” of FIG. 8. FIG. 10 illustrates an enlarged view of an area “F” of FIG. 9. The pressure container 1a of FIG. 6 to FIG. 10 may be similar to the pressure container 1 of FIG. 1 to FIG. 5, except for the structure of the sealing structure 5a and the structure of the recesses (e.g., the first recess 223a and the second recess 223b). In addition, the upper buffer material 61 may further include an intermediate buffer material 61c.

As shown in FIG. 10, the sealing structure 5a may include a first portion 51 and a second portion 52 separated from the first portion 51. The first portion 51 may be spaced apart from the second portion 52. The first fixing portion 22 may define a first recess 223a and a second recess 223b. The first recess 223a may be used for accommodating the first portion 51 of the sealing structure 5a. The second recess 223b may be used for accommodating the second portion 52 of the sealing structure 5a.

The first recess 223a may be recessed from the bottom surface 222 of the first fixing portion 22, and may be communicated with the gap 15. Thus, the first recess 223a may be a portion of the gap 15. The first recess 223a may have a first inner surface 2231a, a second inner surface 2232a opposite to the first inner surface 2231a, and a top inner surface 2233a extending between the first inner surface 2231a and the second inner surface 2232a.

The second recess 223b may be recessed from the bottom surface 222 of the first fixing portion 22, and may be communicated with the gap 15. Thus, the second recess 223b may be a portion of the gap 15. The second recess 223b may have a first inner surface 2231b, a second inner surface 2232b opposite to the first inner surface 2231b, and a top inner surface 2233b extending between the first inner surface 2231b and the second inner surface 2232b.

The second inner surface 2232a of the first recess 223a and the second inner surface 2232b of the second recess 223b may collectively define an intermediate portion 25. Thus, the first fixing portion 22 may include the intermediate portion 25 between the first recess 223a and the second recess 223b. The intermediate portion 25 may taper away from the bottom surface 222 of the first fixing portion 22. The second inner surface 2232a of the first recess 223a may not parallel with the second inner surface 2232b of the second recess 223b. An angle between the second inner surface 2232a of the first recess 223a and the top inner surface 2233a of the first recess 223a may be less than 90 degrees. An angle between the second inner surface 2232b of the second recess 223b and the top inner surface 2233b of the second recess 223b may be less than 90 degrees. The tapered intermediate portion 25 may be configured to readily hold the first portion 51 of the sealing structure 5a in the first recess 223a, and may be configured to readily hold the second portion 52 of the sealing structure 5a in the second recess 223b.

The first portion 51 may further include a first protrusion 515 protruding from the first main portion 510 and opposite to the first lower portion 512. An angle between an upper surface 5151 (e.g., a bevel edge) of the first protrusion 515 and a lower surface 5152 of the first protrusion 515 may be less than 90 degrees, less than 70 degrees, or less than 50 degrees. The first protrusion 515 may be triangular. An angle between the upper surface 5151 of the first protrusion 515 and a lateral surface 517 of the first main portion 510 may be greater than 90 degrees, greater than 110 degrees, or greater than 130 degrees. The lower surface 5152 of the first protrusion 515 may not contact the top surface 321 of the second fixing portion 32 of the inner chamber 3.

The second portion 52 may further include a second protrusion 525 protruding from the second main portion 520 and opposite to the second lower portion 522. An angle between an upper surface 5251 of the second protrusion 525 and a lower surface 5252 of the second protrusion 525 may be less than 90 degrees, less than 70 degrees, or less than 50 degrees. The second protrusion 525 may be triangular. An angle between the upper surface 5251 of the second protrusion 525 and a lateral surface 527 of the second main portion 520 may be greater than 90 degrees, greater than 110 degrees, or greater than 130 degrees. The lower surface 5252 of the second protrusion 525 may not contact the top surface 321 of the second fixing portion 32 of the inner chamber 3.

The first protrusion 515 of the first portion 51 and the second protrusion 525 of the second portion 52 may be configured to hold the intermediate buffer material 61c of the upper buffer material 61. The intermediate buffer material 61c of the upper buffer material 61 may be disposed under the intermediate portion 25 of the first fixing portion 22. Thus, the intermediate buffer material 61c may be disposed between the first portion 51 and the second portion 52 of the sealing structure 5a. The intermediate buffer material 61c may be in a trapezoid shape, and may taper away from the bottom surface 222 of the first fixing portion 22 of the outer chamber 2. One end of the intermediate buffer material 61c may be clamped by the upper surface 5151 of the first protrusion 515 of the first portion 51 and the bottom surface 222 of the first fixing portion 22 of the outer chamber 2. The other end of the intermediate buffer material 61c may be clamped by the upper surface 5251 of the second protrusion 525 of the second portion 52 and the bottom surface 222 of the first fixing portion 22 of the outer chamber 2. A top surface of the intermediate buffer material 61c may contact the bottom surface 222 of the first fixing portion 22 of the outer chamber 2. A bottom surface of the intermediate buffer material 61c may not contact the top surface 321 of the second fixing portion 32 of the inner chamber 3.

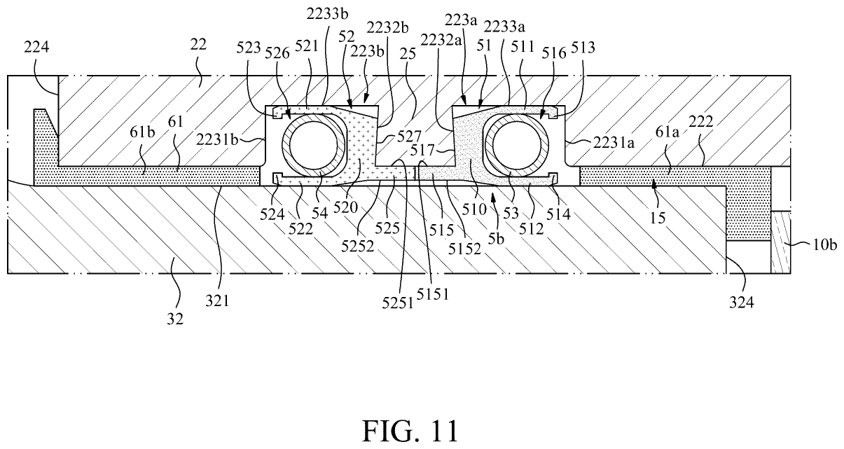

FIG. 11 illustrates a cross-sectional view of a sealing structure 5b according to some embodiments of the present disclosure. The sealing structure 5b of FIG. 11 is similar to the sealing structure 5a of FIG. 10, except that both the first protrusion 515 and the second protrusion 525 may be rectangular, and may contact each other. The intermediate buffer material 61c may be omitted. The upper surface 5151 (e.g., a top surface) of the first protrusion 515 of the first portion 51 may contact the bottom surface 222 of the first fixing portion 22 of the outer chamber 2. The upper surface 5251 (e.g., a top surface) of the second protrusion 525 of the second portion 52 may contact the bottom surface 222 of the first fixing portion 22 of the outer chamber 2. In some embodiments, a material of the first portion 51 may be different from a material of the second portion 52.

In some embodiments, a pressure container includes an outer chamber, an inner chamber and a sealing structure. The outer chamber defines a first cavity. The outer chamber includes a first fixing portion. The inner chamber is disposed in the first cavity and defines a second cavity. The inner chamber includes a second fixing portion. The sealing structure is disposed adjacent to a gap between the first fixing portion and the second fixing portion, and is configured to seal the gap between the first fixing portion and the second fixing portion. The sealing structure includes a first portion and a second portion. The first portion defines a first groove opening toward a first direction. The second portion defines a second groove opening toward a second direction opposite to the first direction. The first portion surrounds the second portion.

In some embodiments, the pressure container may further include a base portion that is disposed under the second fixing portion and is detachably attached to the first fixing portion.

In some embodiments, the pressure container may further include a fastener configured to secure the base portion to the first fixing portion.

In the pressure container, the first fixing portion may define a recess for accommodating the sealing structure.

In the pressure container, the first fixing portion may further define a first opening and a second opening. The first opening is recessed from a first inner surface of the recess for accommodating a first upper extending portion of the first portion of the sealing structure. The second opening is recessed from a second inner surface of the recess for accommodating a second upper extending portion of the second portion of the sealing structure.

In the pressure container, the first fixing portion may define a first recess for accommodating the first portion of the sealing structure and a second recess for accommodating the second portion of the sealing structure.

In the pressure container, the first fixing portion may include an intermediate portion between the first recess and the second recess, wherein the intermediate portion tapers away from a bottom surface of the first fixing portion.

The pressure container may further include: an upper buffer material interposed between the first fixing portion and the second fixing portion; and a lower buffer material interposed between the second fixing portion and the base portion.

The pressure container may further include an intermediate buffer material disposed between the first portion and the second portion of the sealing structure.

In some embodiments, a sealing method includes: providing an outer chamber, wherein the outer chamber defines a first cavity; providing an inner chamber and a sealing structure, wherein the inner chamber is disposed in the first cavity and defines a second cavity, wherein the sealing structure is disposed between the outer chamber and the inner chamber, wherein the sealing structure includes a first portion and a second portion, the first portion defines a first groove opening toward a first direction, the second portion defines a second groove opening toward a second direction opposite to the first direction, wherein the first portion surrounds the second portion; and securing the outer chamber and the inner chamber.

In the sealing method, the sealing structure may further include a first supporter disposed in the first groove and a second supporter disposed in the second groove, wherein in the step of securing the outer chamber and the inner chamber, the first supporter compresses a first upper portion of the first portion to create a firm contact with the outer chamber, and compresses a first lower portion of the first portion to create a firm contact with the inner chamber, wherein the second supporter compresses a second upper portion of the second portion to create a firm contact with the outer chamber, and compresses a second lower portion of the second portion to create a firm contact with the inner chamber.

The sealing method may further include providing a base portion, wherein the step of securing the outer chamber and the inner chamber includes securing the outer chamber and the base portion to clamp a portion of the inner chamber.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A sealing structure, comprising:
a first portion defining a first groove opening toward a first direction; and
a second portion defining a second groove opening toward a second direction opposite to the first direction, wherein the first portion surrounds the second portion.

2. The sealing structure of claim 1, further comprising:
a first supporter disposed in the first groove; and
a second supporter disposed in the second groove.

3. The sealing structure of claim 2, wherein both the first supporter and the second supporter are resilient structures.

4. The sealing structure of claim 2, wherein both the first supporter and the second supporter are hollow structures.

5. The sealing structure of claim 2, wherein both the first supporter and the second supporter are springs.

6. The sealing structure of claim 2, wherein a material of the first portion and the second portion includes resin, and a material of the first supporter and the second supporter includes metal.

7. The sealing structure of claim 1, wherein both the first portion and the second portion are annular structures.

8. The sealing structure of claim 1, wherein the first portion and the second portion are integral with each other.

9. The sealing structure of claim 1, wherein the first portion and the second portion are separated from each other.

10. The sealing structure of claim 1, wherein the first portion includes a first main portion, a first upper portion and a first lower portion collectively define the first groove, wherein both the first upper portion and the first lower portion extend from the first main portion, one end of the first upper portion includes a first upper extending portion extending toward the first lower portion, and one end of the first lower portion includes a first lower extending portion extending toward the first upper portion.

11. The sealing structure of claim 10, wherein the first main portion, the first upper portion and the first lower portion collectively form a U-shaped structure, the first upper portion and the first upper extending portion collectively form an L-shaped structure, the first lower portion and the first lower extending portion collectively form an L-shaped structure.

12. The sealing structure of claim 10, wherein the first portion further includes a first protrusion protruding from the first main portion and opposite to the first lower portion.

13. The sealing structure of claim 12, wherein an angle between an upper surface of the first protrusion and a lower surface of the first protrusion is less than 90 degrees.

14. The sealing structure of claim 12, wherein an angle between an upper surface of the first protrusion and a lateral surface of the first main portion is greater than 90 degrees.

15. The sealing structure of claim 1, wherein the second portion includes a second main portion, a second upper portion and a second lower portion collectively define the second groove, wherein both the second upper portion and the second lower portion extend from the second main portion, one end of the second upper portion includes a second upper extending portion extending toward the second lower portion, and one end of the second lower portion includes a second lower extending portion extending toward the second upper portion.

16. The sealing structure of claim 15, wherein the second main portion, the second upper portion and the second lower portion collectively form a U-shaped structure, the second upper portion and the second upper extending portion collectively form an L-shaped structure, the second lower portion and the second lower extending portion collectively form an L-shaped structure.

17. The sealing structure of claim 15, wherein the second portion further includes a second protrusion protruding from the second main portion and opposite to the second lower portion.

18. The sealing structure of claim 17, wherein an angle between an upper surface of the second protrusion and a lower surface of the second protrusion is less than 90 degrees.

19. The sealing structure of claim 17, wherein an angle between an upper surface of the second protrusion and a lateral surface of the second main portion is greater than 90 degrees.

20. A pressure container, comprising:
an outer chamber defining a first cavity, wherein the outer chamber includes a first fixing portion;
an inner chamber disposed in the first cavity and defining a second cavity, wherein the inner chamber includes a second fixing portion; and
a sealing structure disposed adjacent to a gap between the first fixing portion and the second fixing portion, and configured to seal the gap between the first fixing portion and the second fixing portion, wherein the sealing structure comprises:
a first portion defining a first groove opening toward a first direction; and
a second portion defining a second groove opening toward a second direction opposite to the first direction, wherein the first portion surrounds the second portion.
